(19) United States
(12) Patent Application Publication
(10) Pub. No.: US 2009/0217964 A1
(43) Pub. Date: Sep. 3, 2009

(54) DEVICE, SYSTEM, AND METHOD FOR IMPROVING THE EFFICIENCY OF SOLAR PANELS

(75) Inventors: Jack Arthur Gilmore, Fort Collins, CO (US); Eric Seymour, Fort Collins, CO (US)

Correspondence Address: Neugeboren O'Dowd PC, 1227 Spruce Street, SUITE 200, BOULDER, CO, 80302, US

(73) Assignee: ADVANCED ENERGY INDUSTRIES, INC.

(21) Appl. No.: 12/189,189

(22) Filed: Aug. 10, 2008

Related U.S. Application Data
(63) Continuation-in-part of application No. 11/861,881, filed on Sep. 26, 2007.

(51) Int. Cl. H01L 31/042

(52) U.S. Cl. 136/244

(57) ABSTRACT

A system, method and apparatus are disclosed for improving an operating efficiency of a photovoltaic array. In one embodiment, the method includes arranging a first portion of a photovoltaic array so that the first portion of the photovoltaic array operates above a ground potential; switchably coupling an output of the first portion of the photovoltaic array to a power supply so as to enable the power supply to apply a voltage to the output of the first portion of the photovoltaic array; arranging a second portion of the photovoltaic array so that the second portion of the photovoltaic array operates below a ground potential; and switchably coupling an output of the second portion of the photovoltaic array to the power supply so as to enable the power supply to apply a voltage to the output of the second portion of the photovoltaic array.

### PRIORITY

The present application is a continuation-in-part of U.S. patent application Ser. No. 11/861,881, filed Sep. 26, 2007, entitled: PHOTOVOLTAIC CHARGE ABATEMENT DEVICE, SYSTEM, AND METHOD, which is incorporated by reference herein in its entirety.

### FIELD OF THE INVENTION

This invention relates generally to apparatus and methods for converting solar energy to electrical energy, and more specifically to apparatus and methods for more efficient conversion of solar energy to electrical energy.

### BACKGROUND OF THE INVENTION

The transformation of light energy into electrical energy using photovoltaic (PV) devices has been known for a long time and these photovoltaic devices are increasingly being implemented in residential, commercial, and industrial applications. Although developments and improvements have been made to these photovoltaic devices over the last few years to improve their efficiency, the efficiency of the photovoltaic devices is still a focal point for continuing to improve the economic viability of photovoltaic devices.

Photovoltaic modules are commonly connected with a negative lead of the PV tied to ground so that the module is put into operation at high positive voltages with respect to earth ground. In this type of configuration, however, it has been discovered that “surface polarization” of the module can occur. Surface polarization typically results in an accumulation of static charge on the surface of the solar cells.

In some solar panels, the front surface of the cells are coated with a material that can become charged. This layer performs much like the gate of a field-effect transistor. A negative charge at the surface of the solar cell increases hole-electron recombination When this happens, surface polarization reduces the output current of the cell.

Surface polarization can occur when a module is put into operation at high positive voltages. If the module is operated at a positive voltage with respect to the earth ground, for example, minute leakage current may flow from the cells of the module to ground. As a result, over time, a negative charge is left on the front surface of a cell. And this negative charge attracts positive charge (holes) from a bottom layer of the cell to the front surface where the holes recombine with electrons, and the holes are lost instead of collecting at the positive junction of the module. As a consequence, the current that is produced by the cell is reduced.

Although modules may be operated at negative voltage with respect to ground to prevent surface polarization, this type of architecture prevents bipolar inverters, or inverters with floating arrays, from being utilized because a portion of the photovoltaic array (typically one-half of the array) is operated above ground potential when a bipolar inverter is utilized. And bipolar inverters are typically more efficient than monopolar inverters, in part, because bipolar inverters may be operated at higher voltages, which reduces current losses. As a consequence, it would be beneficial to be able to efficiently utilize bipolar inverters, or inverters with floating arrays, in connection with photovoltaic modules without encountering the deleterious effects of charge accumulation on the photovoltaic modules.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

In one exemplary embodiment, the present invention may characterized as a method comprising: arranging a first portion of a photovoltaic array so that the first portion of the photovoltaic array operates above a ground potential; switchably coupling an output of the first portion of the photovoltaic array to a power supply so as to enable the power supply to apply a voltage to the output of the first portion of the photovoltaic array; arranging a second portion of the photovoltaic array so that the second portion of the photovoltaic array operates below a ground potential; and switchably coupling an output of the second portion of the photovoltaic array to the power supply so as to enable the power supply to apply a voltage to the output of the second portion of the photovoltaic array.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 is a block diagram depicting an exemplary embodiment of a power delivery system;

FIG. 2 is a block diagram depicting an exemplary embodiment in which the charge abatement portion depicted in FIG. 1 is realized by a negative power supply;

FIG. 3 is a block diagram depicting another embodiment in which the charge abatement portion depicted in FIG. 1 is realized, at least in part, by a negative power supply;

FIG. 4 is a block diagram depicting yet another embodiment of the present invention in which the charge abatement portion depicted in FIG. 1 is realized, at least in part, by a charged conductor;

FIG. 5 is block diagram depicting yet another embodiment in which the charge abatement portion depicted in FIG. 1 is realized, at least in part, by a charged conductor;

FIG. 6 is a partial and cut-a-way view of an exemplary embodiment of a photovoltaic module;

FIG. 7 is a schematic drawing depicting an exemplary photovoltaic assembly that includes a charged conductor;

FIG. 8 is a schematic view of yet another embodiment in which the charged conductors depicted in FIGS. 4 and 5 are realized by a charged conductor that is disposed upon a surface of a photovoltaic module; and

FIG. 9 is a flowchart depicting an exemplary method in accordance with several embodiments;

FIG. 10 is a block diagram depicting another embodiment of the charge abatement portion depicted in FIG. 1; and

FIG. 11 is a flowchart depicting an exemplary method that may be carried out in connection with one or more of the embodiments.

### DETAILED DESCRIPTION

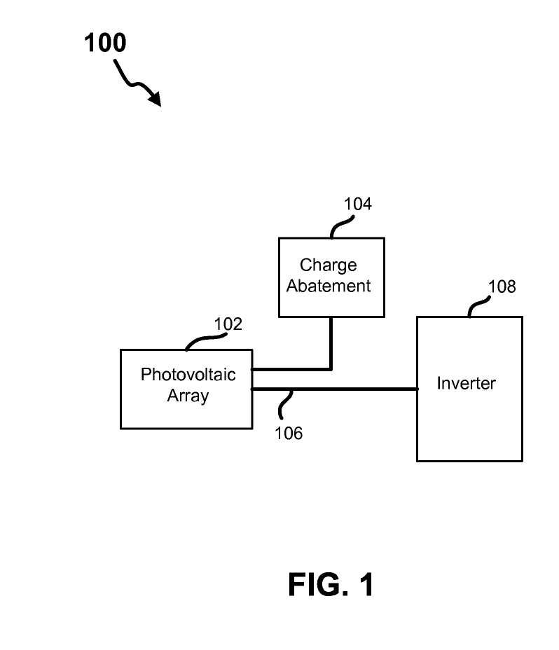

Referring now to the drawings, where like or similar elements are designated with identical reference numerals throughout the several views, and referring in particular to FIG. 1, it is a block diagram depicting a power delivery system 100 including a photovoltaic array 102 that is coupled to both a charge abatement portion 104 and in the inverter 108.

In general, the photovoltaic array 102 converts solar energy to DC electrical power, and applies the DC power to the inverter 108, which converts the DC power to AC power (e.g., three-phase power). The charge abatement portion 104 in this embodiment is configured to mitigate the adverse consequences of a charge (e.g., negative charge) that may accumulate on the surface of one or more modules of the photovoltaic array 102.

In many embodiments, the charge abatement portion 104 reduces an amount of surface charge that the photovoltaic array would ordinarily accumulate if the charge abatement portion 104 were not in place. In some embodiments for example, the charge abatement portion 104 prevents deleterious charges from building up the surface of one or more modules of the photovoltaic array 102 in the first place. And in other embodiments, the charge abatement portion 104 removes or reduces a charge that has accumulated on the surface of one or modules of the array 102.

It should be recognized that the block diagram depicted in FIG. 1 is merely logical. For example, the charge abatement portion 104 in some implementations is housed within the inverter 108, and in other implementations the charge abatement portion 104 is realized as a separate piece of hardware from the inverter and array 102. In yet other embodiments the charge abatement portion 104 is implemented in connection with the photovoltaic array 102 (e.g., integrated with or in close proximity to the array 102).

As discussed further herein, in some embodiments the photovoltaic array 102 is a bipolar array, and in many of these embodiments, at least a portion of the array 102 is disposed so as to operate at a positive voltage with respect to ground. But this is certainly not required, and in other embodiments the photovoltaic array 102 is a monopolar array, which in some variations operates at voltages substantially higher than ground.

In addition, one of ordinary skill in the art will appreciate that the photovoltaic array 102 may include a variety of different type photovoltaic cells that are disposed in a variety of different configurations. For example, the photovoltaic cells may be arranged in parallel, in series or a combination thereof. And the inverter may be realized by a variety of inverters. In some embodiments, for example, the inverter 108 is a bipolar inverter (e.g., an inverter sold under the trade name SOLARON by Advanced Energy, Inc. of Fort Collins, Colo.), but this is certainly not required and in other embodiments, the inverter 108 realized by one or more of a variety of monopolar inverters, which are well known to one of ordinary skill.

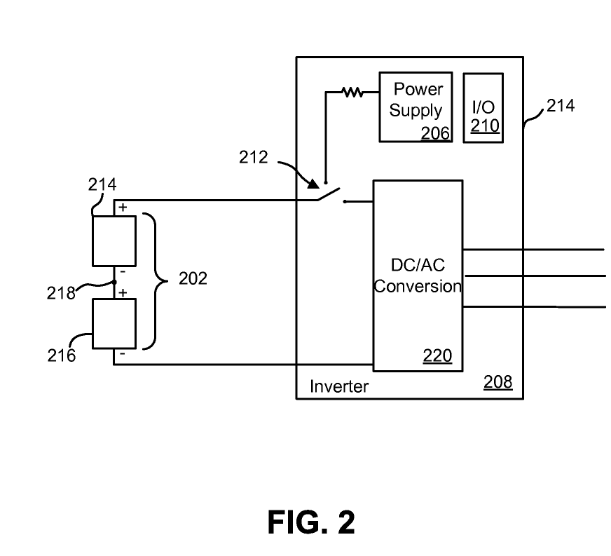

Referring next to FIG. 2, shown is a block diagram depicting an exemplary embodiment in which the charge abatement portion 104 depicted in FIG. 1 includes a negative power supply 206. As shown, a photovoltaic array 202 in this embodiment is coupled via switch 212 to the power supply 206, which resides within a housing 214 of an inverter 208. In addition, the array 202 is also coupled to a DC/AC conversion module 220, which is configured to convert DC power from the photovoltaic array 202 to AC power (e.g., 3-phase AC power). The array 202 in many variations of this embodiment includes N-type base panels. In alternative embodiments, the panels of the array 202 may be constructed utilizing P-type base panels, and in these embodiments, a positive power supply may be switchably coupled to the negative rail of the second array 216 and configured to operate as in much the same way as described below to carry out charge abatement upon the second array 216.

Although not required, the photovoltaic array 202 in this embodiment is a bipolar array that includes a first portion 214 and a second portion 216 that are coupled at a node 218 that is near, or at, a ground potential. As a consequence, the first portion 214 of the array 202 operates above the ground potential and the second portion 216 of the array 202 operates below the ground potential. In many embodiments, each of the first and second portions 214, 216 of the photovoltaic array 202 includes several photovoltaic modules that may be arranged in series, parallel and/or series-parallel combinations.

In operation, before the photovoltaic array 202 begins applying power to the inverter 208 (e.g., before the sun rises), a negative voltage (e.g., −600 VDC) is applied by the power supply 206, via the switch 212, to a positive lead of the first portion 214 of the photovoltaic array 202. In this way, any negative charge that has accumulated on surfaces of the modules in the array 202 is swept away so that the array 202 is capable of operating at its nominal efficiency.

As a consequence, when the array 202 begins to convert solar energy to DC electrical energy (e.g., at sunrise), the array provides power more efficiently than it would with a negative charge accumulation. And in some embodiments, the remaining charge at the end of the day is still positive due to an accumulation of a positive charge attracted to a surface of the modules in the array 202 by the applied negative voltage at night.

In many embodiments, once the array 202 is no longer producing power (e.g., when the sun has set), the negative voltage is again applied to the positive lead of the array 202 to sweep the charge from the array 202. In this way, any reduced positive charge that has drained off the surface of one or more of the modules in array 102 is removed or substantially reduced, and the array 102 operates at an improved efficiency.

In alternative embodiments (e.g., when the array 202 includes P-type base panels), the negative power supply 206 may be replaced by a positive power supply that is switchably coupled to the negative rail of the second portion 216 the array 202. In these alternative embodiments, the positive power supply may be operated in substantially the same manner as the negative power supply 206 as described above to sweep a positive charge that may have accumulated on surfaces of the modules in the array 202.

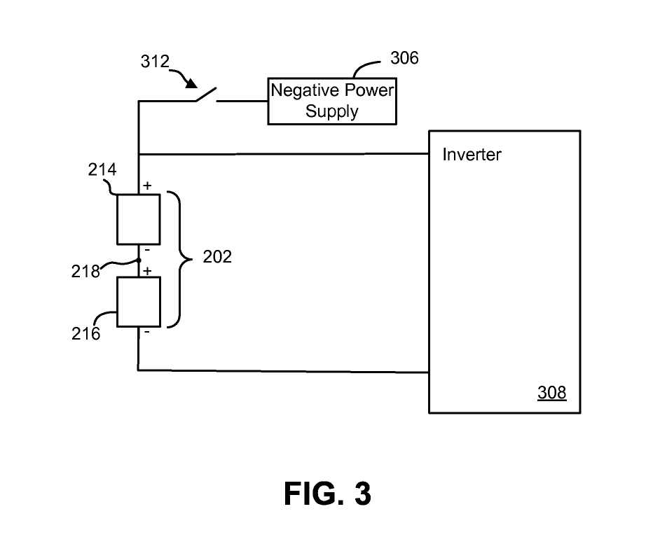

Referring next to FIG. 3, shown is a block diagram depicting another embodiment in which the charge abatement portion 104 depicted in FIG. 1 is realized, at least in part, by a negative power supply 306. As shown, this embodiment is similar to the embodiment described with reference to FIG. 2, but the power supply 306 in this embodiment is disposed externally to an inverter 308, so that, for example, the power supply 306 may be used in connection with an inverter already deployed (e.g., the power supply 306 may be implemented as a retrofit). In operation, the power supply 306 in this embodiment operates in substantially the same manner as the power supply 206 to sweep charge from the array 202.

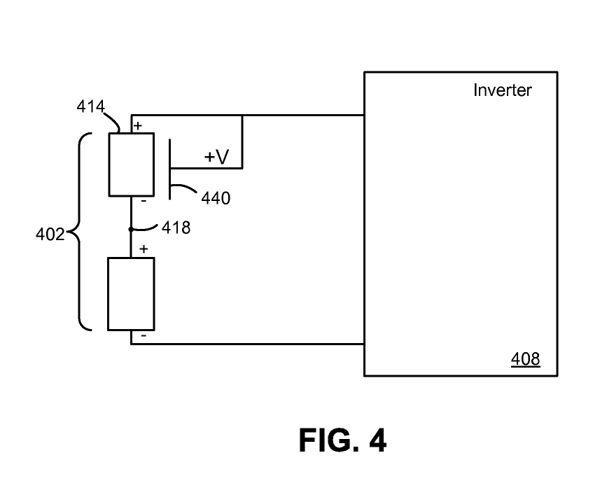

Referring next to FIG. 4, shown is a block diagram depicting yet another embodiment of the present invention in which the charge abatement portion 104 depicted in FIG. 1 is realized, at least in part, by a charged conductor 440. As shown, a conductor 440 is coupled to positive lead of a photovoltaic array 402 and disposed in close proximity to a surface of one or more modules of a first portion 414 of the photovoltaic array 404 that operates at positive voltage with respect to ground 418. As a consequence, the positive charge of the conductor 440 repels positive holes that would ordinarily be attracted to a surface of the module so the holes are eventually collected at the positive junction. As a consequence, the current reduction ordinarily experienced (due to hole recombination with negative charges resident on the front surface of the cell) is abated.

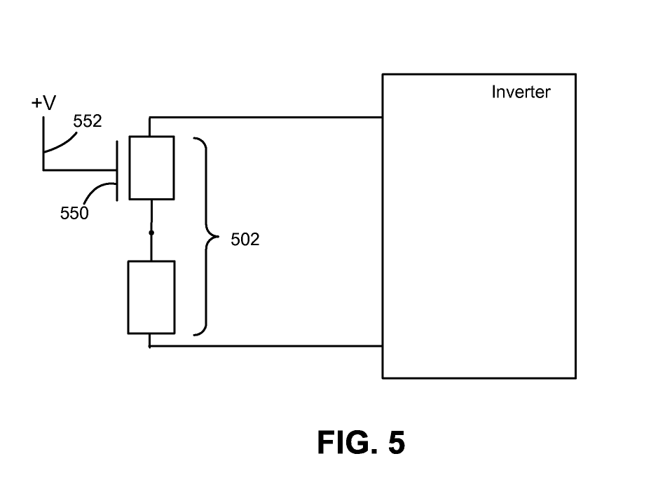

Referring next to FIG. 5 shown is block diagram depicting yet another embodiment in which the charge abatement portion depicted in FIG. 1 is realized, at least in part, by a charged conductor 550. As shown, this embodiment is similar to the embodiment described with reference to FIG. 4, but a charged conductor 550 is tied to a positive potential 552 that is separate from the positive lead of the array 502. In one embodiment, the positive potential is 1000 VDC, but this is certainly not required, and in other embodiments the positive potential that is applied to the conductor is one or more other voltages (e.g., 500 VDC).

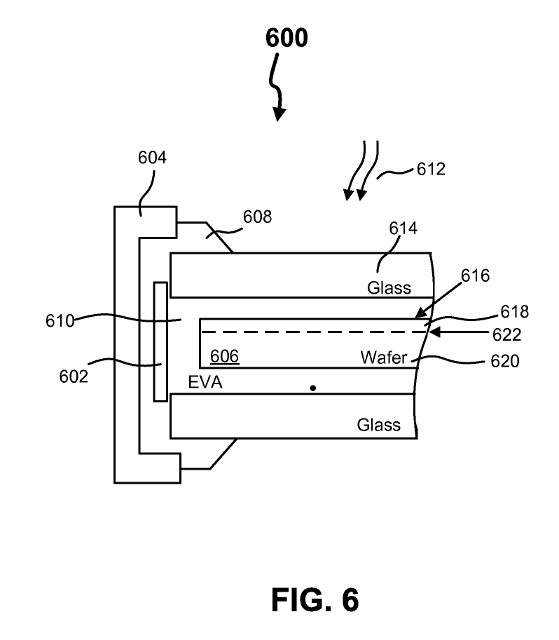

Referring next to FIG. 6 shown in is a partial and cut-a-way view of an exemplary embodiment of a photovoltaic module 600. As shown, in this embodiment the conductors 440, 550 described with reference to FIGS. 4 and 5, respectively, are realized by a conductive ring 602 (e.g., a guard ring) interposed between a frame 604 and a wafer 606 of the module 600. As depicted, the wafer in this embodiment includes a top layer 618 (e.g., a P-type material) and a bottom layer 620 (e.g., an N-type material) that meet at junction 622. As shown, the frame 604 is coupled to an insulator 608 (e.g., rubber) and the ring 602 is interposed between the insulator 608 and an ethyl vinyl acetate (EVA) layer 610, which surrounds the wafer 606.

In this embodiment, while solar energy 612 is imparted to the wafer 606 through a glass layer 614 and the EVA 610, the positive potential of the ring 602 conducts through the EVA 610 or on the inner or outer surface of the glass cover 614 so as to place a positive charge upon the EVA 610, which repels positive charges that would ordinarily be attracted from the bottom layer 620 to the top layer 618 so the positive charges are guided back to the collecting junction in the bottom layer 620 instead of being lost by recombination with negative charges at or near the surface 616 of the top layer 618.

Although not depicted in FIG. 6, in one embodiment a lead is coupled to the ring and disposed through the insulator 608 so as to allow the ring 602 to be coupled to a positive potential (e.g., potential 552). In another embodiment, the ring is conductively coupled to a positive lead of the module. Although not required, the ring in some embodiments is realized by a conductive tape (e.g., aluminum, tinned copper, and/or lead) that is placed around a periphery of the EVA 610 and separated from the frame 604 by the insulator 608.

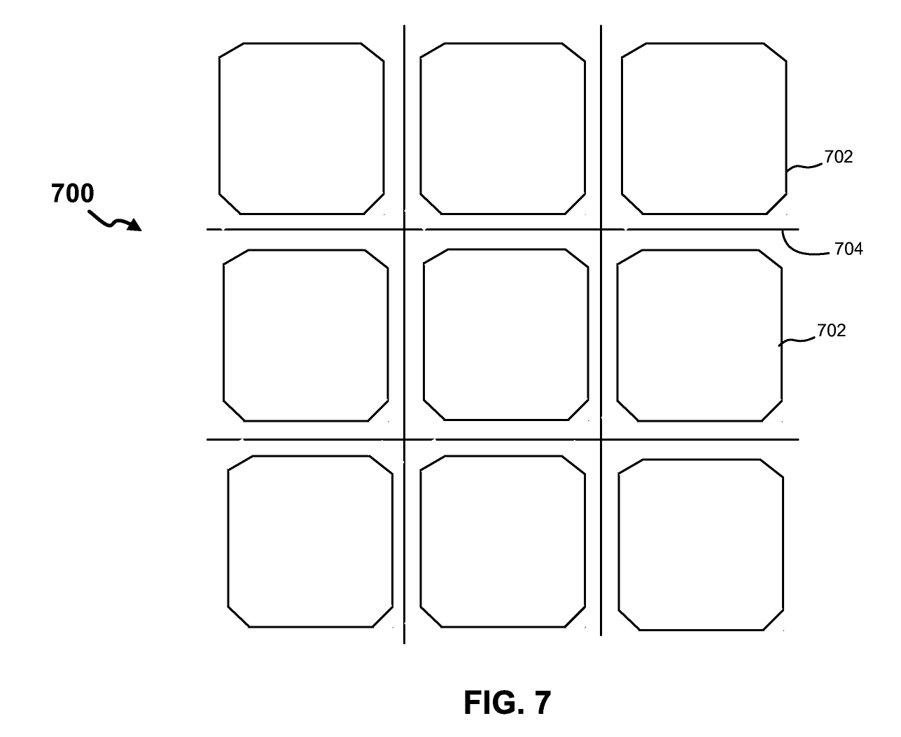

Referring next to FIG. 7, it is a schematic drawing depicting a photovoltaic assembly 700 that includes collection of photovoltaic modules 702 and a charged conductor 704 that is arranged so as to surround each module 702 while being interposed between the modules 702. In this embodiment, the conductors 440, 550 described with reference to FIGS. 4 and 5 are realized by the charged conductor 704, and as a consequence, in one embodiment, the charged conductor 704 is coupled to a positive lead from the collection of the modules, and in another embodiment, the charged conductor is coupled to a separate positive potential (e.g., potential 552).

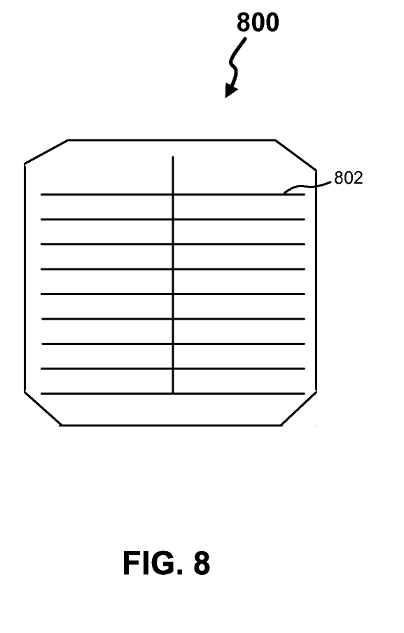

Referring to FIG. 8, shown is a schematic view of yet another embodiment in which the conductors 440, 550 described with reference to FIGS. 4 and 5 are realized by a charged conductor 802 that is insulated from current-carrying collection electrodes (not shown) and is disposed upon a surface of a module 800. As depicted, the conductor 802 includes a collection of connected linear conductors that are disposed about a surface of the module 800. In some embodiments, the conductor 802 is placed between a glass layer (e.g., glass layer 614) and an EVA layer (e.g., EVA layer 610). In other embodiments, the conductor 802 is placed upon a surface of the wafer (e.g., by deposition). In yet other embodiments, the conductor 802 is realized by a transparent conductive layer on the inner surface of the glass layer 614. These embodiments are merely exemplary, however, and it is contemplated that the conductor 802 may be disposed in a variety of positions within the module 802, and the conductor 802 may be arranged in a variety of architectural patterns.

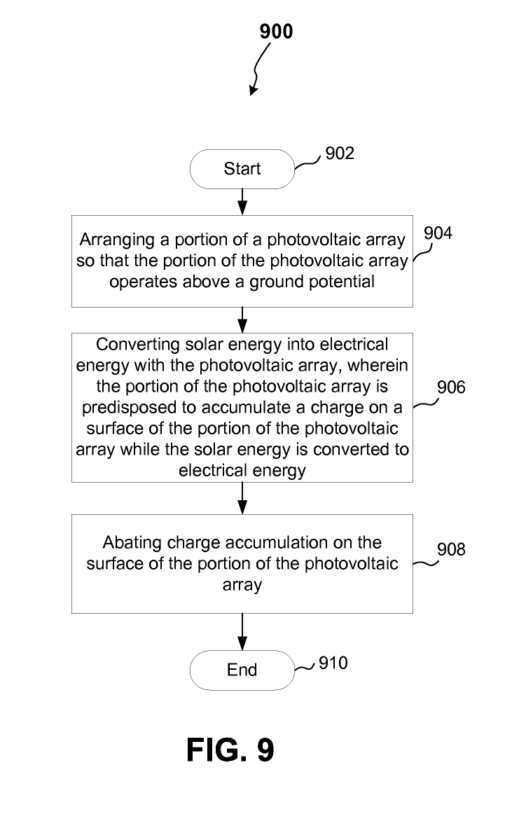

Referring next to FIG. 9, shown is a flowchart depicting an exemplary method that may be carried out in connection with one or more of the embodiments described with reference to FIGS. 1-8. As shown, a portion of the photovoltaic array is arranged so that it operates above ground potential (Blocks 902, 904). In some embodiments, the entire array (e.g., a monopolar array) is operated above ground potential (e.g., the array is negatively grounded), and in other embodiments a first portion of the array is negatively grounded and a second portion of the array is positively grounded so that the first portion of the array operates above ground potential and the second portion of the array operates below ground potential (e.g., a bipolar array).

As depicted in FIG. 9, solar energy is then converted into electrical energy with the photovoltaic array (Block 906). As discussed, many photovoltaic modules are predisposed to accumulating a charge (e.g., negative charge) on the surface of the module when operating above ground potential, which leads to a degradation in the efficiency of the module. To mitigate against any adverse effects of charge accumulation, the accumulation of charge on the surface of photovoltaic modules is abated (Blocks 908, 910).

As discussed with reference to FIGS. 2 and 3, the accumulation of charge in some embodiments is abated by coupling a positive lead of the photovoltaic array to a negative power supply while the array is offline so as to remove any accumulated negative charge from the array. And in some instances, the negative potential is utilized to accumulate a positive charge on the array so that during subsequent operation, when the array is converting solar energy to electrical energy, any negative charge accumulation during operation is substantially delayed relative to an amount of time that a comparable amount of charge accumulates on an array that is placed in operation without being preconditioned with a negative potential. Moreover, in other embodiments, a portion of the positive charge accumulated during the previous night still remains at the surface of the modules at the end of the day.

In other embodiments discussed with reference to FIGS. 4-8, the adverse effects of an accumulation of charge at the surface of the modules is abated by placing a positive potential in close proximity to a surface of the array so as to reduce or prevent an amount of positive charges, originating from a bottom portion of the modules, from combining with negative charges on the surface of the array.

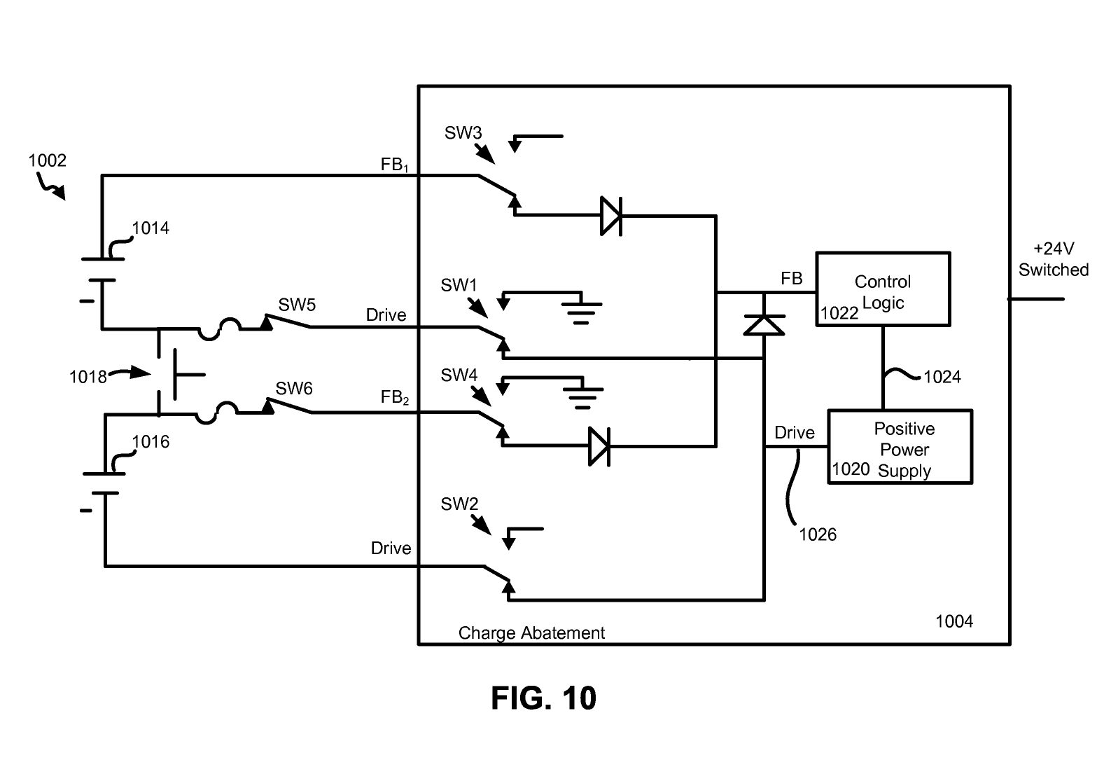

Referring next to FIG. 10, shown is another embodiment of a charge abatement portion 1004 that may be implemented as the charge abatement portion 104 described with reference to FIG. 1. As shown, in this particular embodiment a positive power supply 1020 is configured to apply a positive voltage to the negative rails of both the first 1014 and second 1016 arrays so as to increase the efficiency of both arrays 1014, 1016.

In the embodiment depicted in FIG. 10, the panels of the arrays 1014, 1016 are constructed utilizing P-type base panels, but in alternative embodiments, the panels of the arrays 1014, 1016 are constructed utilizing a N-type base panels, and in these embodiments, the diodes and depicted polarities would be reversed from the depicted arrangement in FIG. 10, and the power supply 1020 would be realized by a negative power supply.

As shown, control logic 1022 in this embodiment is adapted to monitor the potential across the arrays 1014, 1016, and based upon the potential across the arrays 1014, 1016, control switches SW1, SW2, SW3, SW4, SW5, and SW6 so as to couple the charge abatement 1004 portion to the array 1002 when the voltage that is generated by the array 1002 drops below a threshold level and to decouple the charge abatement portion 1004 from the array 1002 when the array 1002 generates voltage at a particular level.

As depicted, the control logic 1022 is switchably coupled to the positive rails of the array 1002 so as to enable the voltage across each of the arrays 1014, 1016 to be monitored. And responsive to the monitored voltage, the control logic 1022 is configured to send a drive signal 1024 to the power supply 1020 to control the voltage that the power supply 1020 applies to each of the negative rails of the arrays 1014, 1016. Although not required, the control logic 1022 in many embodiments is realized by firmware to operate as described further herein, and the power supply 1020 is realized by a 0 to 600 VDC power supply that is configured to vary the voltage that is applied to the arrays based upon the drive signal 1024.

It should be recognized that the block diagram depicted in FIG. 10 is merely logical, and that the functions depicted may be realized by a variety of different components in a variety of different architectures. For example, the charge abatement portion 1004 in some implementations is housed within an inverter (e.g., inverter 108), and in other implementations the charge abatement portion 1004 is realized as a separate piece of hardware from the inverter and array 1002. Similarly, the components of the control logic 1022 and/or the power supply 1020 may be distributed across multiple components (e.g., an inverter, within the charge abatement portion 1004, and/or within one or more other components).

The state of the switches SW1, SW2, SW3, SW4, SW5, and SW6 depicted in FIG. 10 is a state in which the charge abatement portion 1004 is coupled to the array 1002. And when in this state, before the photovoltaic array 1002 begins applying power (e.g., before the sun rises) to an inverter (e.g., inverter 108), a positive voltage (e.g., between 400 VDC and 600 VDC) is applied by the power supply 1020, via switches SW1 and SW2 to negative leads of the first 1014 and second 1016 portions of the photovoltaic array 1002. In this way, any positive charge that has accumulated on surfaces of the modules in the array 1002 is swept away so that the array 1002 is capable of operating at an improved efficiency relative to implementations that do not apply a bias voltage to the arrays.

As the sun begins to rise, the voltage generated by each of the arrays 1014, 1016 begins to increase, and when the voltage of any one of the arrays 1014, 1016 reaches a threshold level (e.g., +/−250VDC), then control logic 1022 prompts the switches SW1, SW2 to change state so as to disengage the positive power supply 1020 from the negative rails of the arrays 1014, 1016, and control logic 1022 prompts switches SW3, SW4 to change state to decouple the control logic 1022 from the positive rails of the arrays 1014, 1016. Once the switches SW1, SW2, SW3, SW4 have changed state, the charge abatement portion 1004 is effectively decoupled from the array 1002. In addition, the PV tie 1018 is closed so as to couple the negative rail of the first array 1014 to the positive rail of the second array 1016, and switches SW5, SW6 are opened.

As the sun goes down, the voltage on the arrays 1014, 1016 decreases and when the power conversion component (e.g., inverter) that is coupled to the array 1002 does not receive sufficient power from the array 1002, it turns off. For example, once the rail-to-rail voltage of the array 1002 falls below a pre-set condition (e.g., 400 Volts), the switches SW1, SW2, SW3, SW4, SW5, and SW6 are triggered to change state from a daytime-state to the state depicted in FIG. 10.

At this point, the power supply 1020 may begin to apply, via the drive lines, a bias to the arrays 1014, 1016. In the exemplary embodiment depicted in FIG. 10, the rail-to-ground voltage of the array 1014, 1016 with the highest rail-to-ground voltage is utilized by the control logic 1022 to control the level of voltage that is applied to the drive lines so that the voltage across either of the arrays 1014, 1016 does not exceed a threshold (e.g., a maximum voltage set by governing electric code). For example, if the voltage across the first array 1014 is +300VDC relative to ground and the voltage across the second array is −200VDC relative to ground, and the maximum permissible voltage across either array 1014, 1016 is +/−600VDC relative to ground, then the power supply 1020 will apply no more than +300 VDC to the negative rails of the arrays 1014, 1016 to limit the voltage across either array to no more than 600VDC.

More specifically, in the exemplary embodiment, the feed back lines FB₁, FB₂ are diode isolated so that the voltage of the array 1014, 1016 with the highest voltage is applied to the control logic 1022, and as a consequence, the voltage of the array 1014, 1016 with the highest voltage is used to control the power supply 1020 so that the output voltage of the power supply 1010 is the particular maximum voltage (e.g., 600VDC) minus the highest voltage across either of the arrays. In this way, the rail-to-ground voltage of the arrays 1014, 1016 may be limited to the particular maximum voltage.

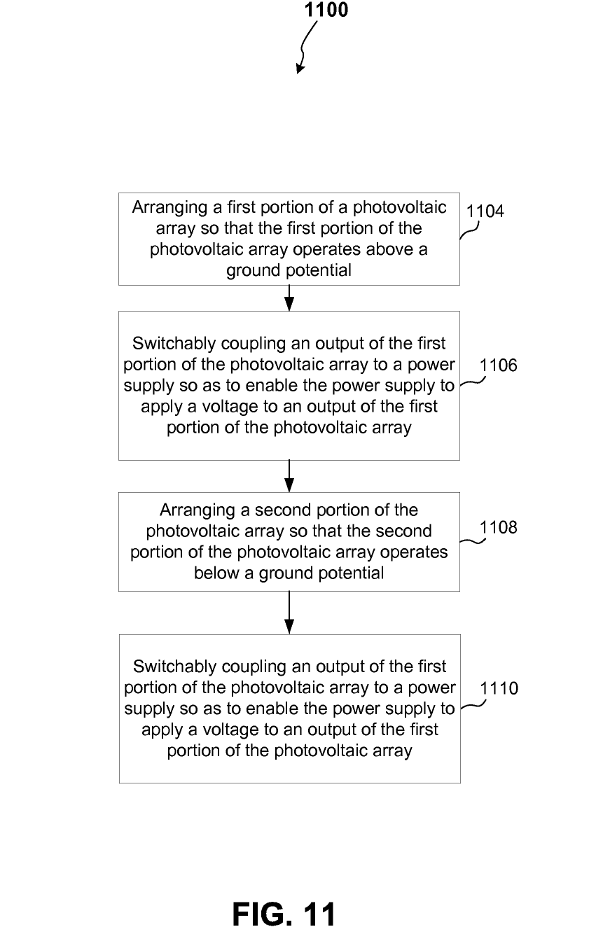

Referring next to FIG. 11, shown is a flowchart depicting an exemplary method that may be carried out in connection with the embodiment depicted in FIG. 10. As shown, a first portion (e.g., the first array 1014) of a photovoltaic array (e.g., array 1002) is arranged so that the first portion of the photovoltaic array operates above a ground potential (Block 1104), and an output (e.g., a negative rail) of the first portion of the photovoltaic array is switchably coupled (e.g., by switch SW1) to a power supply (e.g., power supply 1020) so as to enable the power supply to apply a voltage to the output of the first portion of the photovoltaic array (Block 1106).

In addition, a second portion (e.g., the second array 1016) of the photovoltaic array (e.g., photovoltaic array 1002) is arranged so that the second portion of the photovoltaic array operates below a ground potential (Block 1108), and an output of the second portion of the photovoltaic array is switchably coupled to the power supply so as to enable the power supply to apply a voltage to the output of the second portion of the photovoltaic array (Block 1110).

In this way, before the photovoltaic array 1002 begins applying power (e.g., to the inverter 108) (e.g., before the sun rises), a voltage may be applied by the power supply to sweep undesirable charges that may have accumulated on surfaces of the modules in the array 1002 so that the array 1002 is capable of operating at its nominal efficiency when the array 1002 is placed online.

In conclusion, the present invention provides, among other things, a system and method for improving operation of a photovoltaic array. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims. For example, it is contemplated that yet other embodiments incorporate more than one of the embodiments depicted in FIGS. 2-11.

By way of further example, one of ordinary skill in the art will appreciate that if the structure of the photovoltaic cell is reversed from the exemplary embodiments discussed in FIGS. 1-9, a positive voltage may be applied to a negative terminal of the module at night (instead of a negative voltage being applied to a positive terminal) to sweep positive charges from a surface of the module, and a negative potential may be applied to a charged conductor during the day to prevent electrons from being attracted to (and lost) a positive charge accumulation at a surface of the modules. And if the structure of the cells in the array 1002 described wither reference to FIG. 10 are reversed, a negative power supply may be utilized at night to remove any negative charge that may have accumulated on the array 1002.

What is claimed is:

1. A system comprising:
a first drive line configured to couple to a first photovoltaic array and a second drive line configured to couple to a second photovoltaic array;
at least one feedback line coupled to at least one of the first and second photovoltaic arrays so as to provide an indication of a voltage across at least one of the first and second photovoltaic arrays;
at least one power supply, the at least one power supply being switchably coupled to the first and second drive lines so as to enable the at least one power supply to apply voltage to the first and second drive lines; and
control logic coupled to the at least one feedback line and the at least one power supply, the control logic configured, based upon the indication of the voltage across at least one of the first and second photovoltaic arrays, to control voltage the power supply applies voltage to the first and second drive lines.

2. The system of claim 1, wherein the power supply is a positive power supply and each of the first drive line and the second drive line are coupled to a corresponding one of a negative output of the first array and a negative output of the second array.

3. The system of claim 1, wherein the power supply is a negative power supply and each of the first drive line and the second drive line are coupled to a corresponding one of a positive output of the first array and a positive output of the second array.

4. The system of claim 1, wherein the at least one power supply is a single power supply and the first drive line and the second drive line are coupled together.

5. The system of claim 1, wherein the at least one feedback line includes two diode isolated feedback lines so the indication of the voltage across at least one of the first and second photovoltaic arrays is a single indication of the voltage of the array at the highest voltage.

6. A system comprising:
a photovoltaic array arranged so that a portion of the photovoltaic array operates below a ground potential; and
a charge abating portion coupled to the photovoltaic array that is configured to abate charge accumulation on the surface of the portion of the photovoltaic array that operates below a ground potential.

7. The system of claim 6, including:
a second photovoltaic array arranged so that a portion of the second photovoltaic array operates above a ground potential, a negative rail of the second photovoltaic array is coupled to a positive rail of the photovoltaic array, the charge abating portion coupled to the second photovoltaic array.

8. The system of claim 7, wherein the charge abating portion includes a positive power supply switchably coupled to negative leads of both photovoltaic arrays.

9. The system of claim 8, wherein the positive power supply is housed within an inverter.

10. An apparatus comprising:
a first input configured to couple to a negative rail of a photovoltaic array and a second input configured to couple to a second rail of the photovoltaic array;
a power supply configured to apply a positive voltage with respect to a ground potential; and
a switch configured to couple the positive voltage to the negative rail so as to enable a portion of the photovoltaic array that is substantially at a negative potential to be placed at the positive potential.

11. The apparatus of claim 10 comprising:
a conversion module coupled to the first and second inputs, the conversion module configured to alter at least one characteristic of DC power from the photovoltaic array.

12. The apparatus of claim 11, wherein the conversion module is configured to convert the DC power from the photovoltaic array to AC power.

13. The apparatus of claim 11, wherein the conversion module is a conversion module selected from the group consisting of a conversion module configured to convert DC voltage applied by the array to a higher DC voltage and a conversion module configured to convert DC voltage applied by the array to a lower DC voltage.

14. The apparatus of claim 10, wherein the photovoltaic array includes a first and a second photovoltaic array.

15. A method comprising:
arranging a first portion of a photovoltaic array so that the first portion of the photovoltaic array operates above a ground potential;
switchably coupling an output of the first portion of the photovoltaic array to a power supply so as to enable the power supply to apply a voltage to the output of the first portion of the photovoltaic array;
arranging a second portion of the photovoltaic array so that the second portion of the photovoltaic array operates below a ground potential; and
switchably coupling an output of the second portion of the photovoltaic array to the power supply so as to enable the power supply to apply a voltage to the output of the second portion of the photovoltaic array.

16. The method of claim 15, including:
switchably coupling a negative output of the first portion of the photovoltaic array to a positive power supply so as to enable the positive power supply to apply a positive voltage to the negative output of the first portion of the photovoltaic array.

17. The method of claim 15, including:
switchably coupling a negative output of the second portion of the photovoltaic array to a positive power supply so as to enable the positive power supply to apply a positive voltage to the negative output of the first portion of the photovoltaic array.
